(19) United States
(12) Patent Application Publication
(10) Pub. No.: US 2023/0380082 A1
(43) Pub. Date: Nov. 23, 2023

(54) MULTIFUNCTIONAL DISPLAY DEVICE

(71) Applicant: NETRONIX, INC., JUBEI CITY (TW)

(72) Inventors: KENG FENG LIN, Jubei City (TW); LI FANG FAN, Jubei City (TW); LING LING WU, Jubei City (TW); HUEI YU CHEN, Jubei City (TW)

(21) Appl. No.: 17/811,694

(22) Filed: Jul. 11, 2022

(30) Foreign Application Priority Data
May 20, 2022 (TW) 111205227

(51) Int. Cl. H05K 5/02; H05K 5/00; G09F 3/20

(52) U.S. Cl. CPC H05K 5/0204; H05K 5/0018; G09F 3/208; G06F 3/14

(57) ABSTRACT

The present invention discloses a multifunctional display device, which includes a display unit and a support member. The display unit includes a first side and a second opposite to the first side. The support member is disposed on the first side and includes a reverse hanging unit disposed near the second side. According to requirement, the reverse hanging unit may be used to hang the reversed display unit onto a supporter. While the multifunctional display device is placed on a desk top, the display unit may present the information of a calendar, whereby the multifunctional display device can function as an electronic calendar. While the multifunctional display device is hung reversely via the reverse hanging unit, the display unit may present the information of goods, whereby the multifunctional display device can function as an electronic shelf label.

This application claims priority of Application No. 111205227 filed in Taiwan on 20 May 2022 under 35 U.S.C. § 119; the entire contents of all of which are hereby incorporated by reference.

### BACKGROUND OF THE INVENTION

### Field of the Invention

The present invention relates to a multifunctional display device, particularly to a multifunctional display device applicable to different situations.

### Description of the Prior Art

After energy-efficient and environment-friendly electronic paper (ePaper) acquires technical breakthrough in full-color display, it has been extensively used as electronic labels and electronic shelf labels (ESL) in the marketplaces of retail corporations, such as Carrefour, Walmart, Target, and PX Mart (Taiwan).

The existing display devices, including the electronic paper mentioned above, can only be used in a single direction. Such a limitation may impair the usage of display devices in many situations. The display device may present a calendar, a shelf label, a photo, or a record according to user's requirement. In usage of a display device, the user may place it on a desk, reversely stand it on a plane, or reversely hang it on a hook. Conventional display devices available in the market can be supported by the battery or other components behind the display unit in normal usage. In some situations, no plane can be used to support the battery or other components. Thus, the user can only secure the display device in another way. However, such measures may increase the probability of malfunction or damage of display devices. For example, while the user intends to use the display device as a calendar, he can place it on a desk easily; however, while the user intends to use the display device as a shelf label, he may need to hang it reversely on a hook.

In addition to defining the contents, the housing of a display device needs more designs to overcome the conventional problems, satisfy various requirements, and realize a multifunctional display device.

### SUMMARY OF THE INVENTION

To overcome the abovementioned problems, the present invention provides a multifunctional display device, which comprises a reverse hanging unit, whereby the display device can be hung reversely if no plane can support the display device, wherefore is solved the problem of supporting the display device in different situations.

To achieve the abovementioned objective, the present invention provides a multifunctional display device, which comprises a display unit and a support member. The display unit includes a display surface, a rear surface opposite to the display surface, a first side, and a second opposite to the first side. The support member is disposed on the rear surface and near the first side. The support member includes a first region near the first side, a second region near the second side, and a reverse hanging unit disposed on the second region. The reverse hanging unit is used to hang the reversed display unit onto a supporter.

In a preferred embodiment, the display unit has at least one oblique plane on the first side; the at least one oblique plane is inclined by an angle ranging from 145 degrees to 175 degrees.

In a preferred embodiment, the reverse hanging unit is a groove.

In a preferred embodiment, the groove includes a stop element, which is used to prevent the reverse hanging unit from departing from the supporter.

In a preferred embodiment, the groove includes a recess facing the second side.

In a preferred embodiment, the reverse hanging unit includes at least one hole.

In a preferred embodiment, the multifunctional display device further comprises a transmission port, which is in signal communication with the display unit and enables the display unit to exchange packets with external devices.

In a preferred embodiment, the multifunctional display device further comprises a wireless transmission unit, which is in signal communication with the display unit and enables the display unit to exchange packets with external devices.

In a preferred embodiment, the multifunctional display device further comprises a support base, wherein the support member has a press-fit module disposed in a region near the first side; the support base is used to be press-fitted to the press-fit module, such that the display unit can stand on a plane.

In a preferred embodiment, the display unit includes a battery unit built therein and a charging interface electrically connected with the battery unit.

In comparison with the prior art, the present invention provides a multifunctional display device, which comprises a reverse hanging unit, whereby the display device can be hung reversely if no plane can support the display device, wherefore is solved the problem of supporting the display device in different situations.

### BRIEF DESCRIPTION OF THE DRAWINGS

FIG. 1 is an oblique front view schematically showing a multifunctional display device according to one embodiment of the present invention.

FIG. 2 is an oblique rear view schematically showing a multifunctional display device according to one embodiment of the present invention.

FIG. 3 is a left-side view schematically showing a multifunctional display device according to one embodiment of the present invention.

FIG. 4 is a diagram schematically showing that an assemblage of the multifunctional display and a support base functions as an electronic calendar according to one embodiment of the present invention.

FIG. 5 is a diagram schematically showing that the multifunctional display device is used as an electronic calendar according to one embodiment of the present invention.

FIG. 6 is a diagram schematically showing that the multifunctional display device is used as an electronic shelf label according to one embodiment of the present invention.

### DETAILED DESCRIPTION OF THE INVENTION

The following text and the related drawings will be used to demonstrate the embodiments of the present invention further. The identical symbol is used to designate the similar or identical component in the specification and drawings as far as possible. In the drawings, the shapes and thicknesses may be exaggerated for simplicity and convenience. It should be understood that the elements, which belong to the conventional technology and are well known by the persons having ordinary knowledge in the art, are not necessarily shown in the drawings or described in the specification. Also, it should be understood that the persons skilled in the art can modify or vary the embodiments of the present invention without departing from the spirit of the present invention.

Hereinafter, a description about “an embodiment” or “one embodiment” may be involved in a specified element, structure, or characteristics of at least one embodiment. Therefore, the descriptions about “an embodiment” or “one embodiment” appearing in several positions of the text do not necessarily refer to the same embodiment. Besides, specified elements, structures or characteristics in one or more embodiments may be combined in an appropriate way.

The terms “comprising”, “including”, “having”, “containing” and “involving” mentioned in the specification and claims are open-ended terms and should be interpreted as “contain somethings and may further contain other things”. It is unnecessary for any embodiment or claim to realize all the targets or characteristics disclosed by the present invention. The abstract and title are only to assist in searching for the patent documents but not to limit the scope of the present invention.

Various embodiments are described in the specification referring to the attached drawings. The terms about directions, such as “up”, “down”, “front”, “rear”, “left”, “right”, “internal”, “external”, and “lateral” are used to indicate the directions in the drawings. Therefore, the terms of directions are only used to describe the present invention to enable the readers to understand the present invention but not to limit the scope of the present invention.

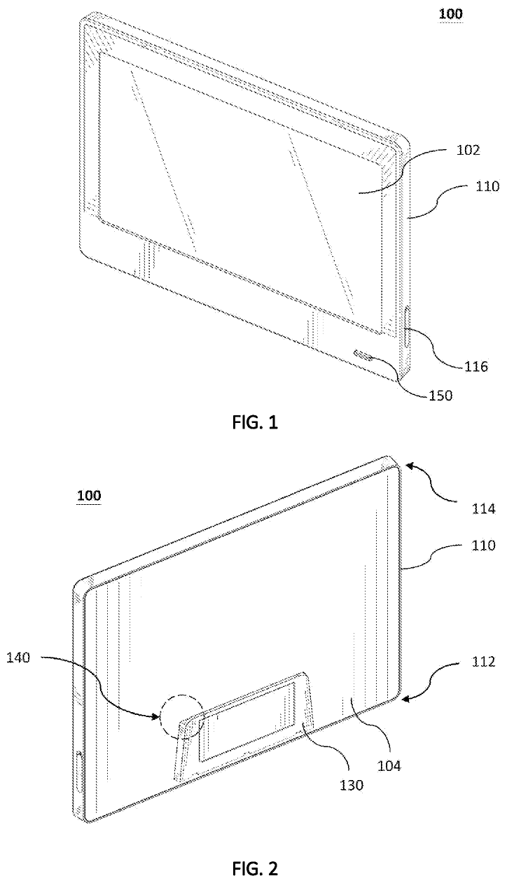

Refer to FIG. 1 and FIG. 2, which are respectively an oblique front view and an oblique rear view schematically showing a multifunctional display device according to one embodiment of the present invention. The multifunctional display device 100 includes a display unit 110 and a support member 130. The display unit 110 includes a display surface 102, a rear surface 104 opposite to the display surface 102, a first side 112, and a second 114 opposite to the first side 112. The first side 112 is the side near the ground while the multifunctional display device 100 stands normally. The second side 114 is the side far away from the ground while the multifunctional display device 100 stands normally. While the multifunctional display device 100 is used normally (i.e., the first side 112 is faced downward, and the second side 114 is faced upward), the multifunctional display device 100 can be stably placed on a desktop via the first side 112 of the display unit 110.

The support member 130 is disposed on the rear surface and near the first side 112. The support member 130 of the multifunctional display device 100 includes a first region near the first side 112, a second region near the second side 114, and a reverse hanging unit 140 disposed on the second region. The reverse hanging unit 140 is used to hang the reversed display unit 110 onto a supporter.

The display unit 110 may be display panel based on a Liquid Crystal Display (LCD) technology, a mini-LED technology, a Micro LED technology, an Organic Light-Emitting Diode (OLED) technology, or a Microencapsulated ElectroPhoretic (MEP) technology. The MEP-based display device is also called ePaper, wherein electric field is applied to rearrange the charged pigment particles; millions of microcapsules, including positively-charged white particles and negatively-charged black particles, are sealed in the display device. In MEP-based display device, upper electrode layers and lower electrode layers are controlled to actuate the charged particles to move. In comparison with the LCD and OLED technologies, which are extensively used in smart phones and televisions, ePaper is limited by the migration velocity of microcapsules and thus has a lower screen refresh rate. However, ePaper can present images via reflecting ambient light. Therefore, ePaper consumes less power and is suitable to be used as shelf labels of merchandise and goods. The existing ePaper can present three-color, four-color, seven-color, or even full-color images, which may be realized via arranging color filter films between the cover plate and the electrode layer or via filling CMYK charged particles into microcapsules.

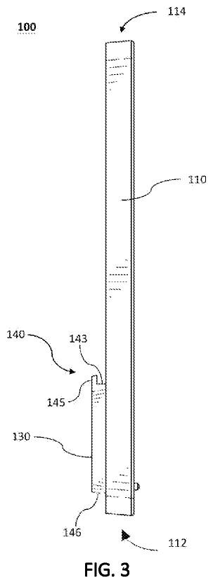

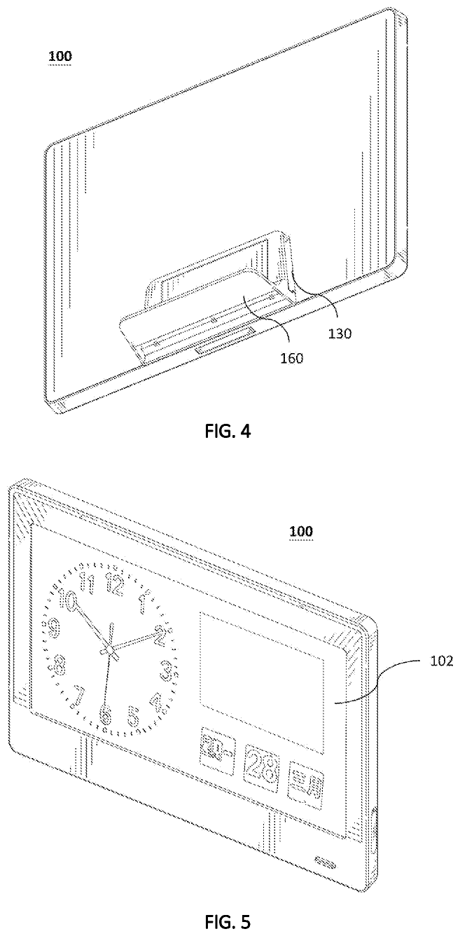

Refer to FIG. 3, which is a left side view schematically showing a multifunctional display device 100 according to one embodiment of the present invention. The display device 110 has at least one oblique plane on the first side 112. A special angular design of the oblique plane enables the multifunctional display device 100 to stand on a plane. In a preferred embodiment, the oblique plane is inclined by an angle ranging from 145 degrees to 175 degrees. In the preferred embodiment, what contacts the desktop is the display unit 110 and the support member 130. According to different requirements, what contacts the desktop may be only the display unit 110 as long as it meets the angular design of the oblique plane. However, the present invention is not limited by these embodiments. Naturally, the first side 112 may be a planar surface. Refer to FIGS. 3-5. FIG. 4 is a diagram schematically showing an assemblage of the multifunctional display, which function as an electronic calendar. FIG. 5 is a diagram schematically showing that the multifunctional display device is used as an electronic calendar. A press-fit member 146 is disposed near the first side 112, and a support base 160 can be press-fitted to the press-fit member 146. While the multifunctional display device 100 is stood on a plane normally, the user himself may define the contents presented by the display unit 110, such as the calendar shown in FIG. 5.

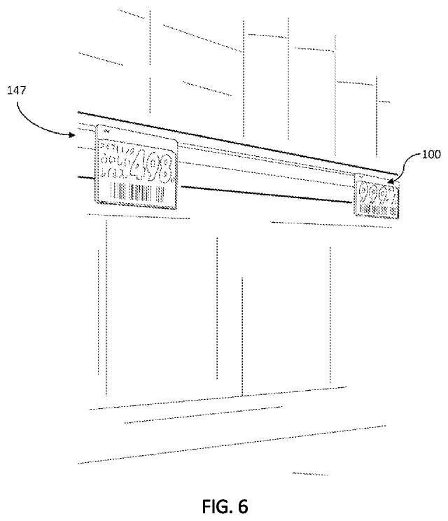

Refer to FIG. 3 again. In some embodiments, the reverse hanging unit 140 includes a groove 143. While the shelf has a supporter 147 in form of a horizontal rod or a like structure, the groove may be used to reversely hang the display unit 110. Refer to FIG. 6, which is a diagram schematically showing that the multifunctional display device is used as an electronic shelf label according to one embodiment of the present invention. In convenience stores and hypermarkets, the shelves usually have supporters 147, which are often in form of horizontal rods. The reversed multifunctional display device 100 can be hung onto the supporter 147 with the groove 143. The present invention can expand the application field of the conventional electronic shelf label in cooperation with the groove 143 and the contents defined by the user himself. In some embodiments, the groove 143 includes a hook-like stop element 145, which is used to prevent the reverse hanging unit 140 from departing from the supporter 147. In a preferred embodiment, the groove has a recess facing the second side 114. The recess can further prevent the reverse hanging unit 140 from departing from the supporter via avoiding the slip of the reverse hanging unit 140.

In some embodiments, the reverse hanging unit 140 includes at least one hook. The user uses the hook to hang the reversed multifunctional display device 100 onto the supporter 147. In some embodiments, the reverse hanging unit 140 includes one hole or more holes arranged symmetrically. The user lets holes be inserted by the hooks (not shown in the drawings) extended from the supporter 147 to hang the reversed multifunctional display device 100.

It should be noted: the present invention does not limit the size of the multifunctional display device 100. The multifunctional display device 100 may be in specification of a tablet computer ranging from 7 in to 10.9 in, in specification of a mobile phone ranging from 5.4 in to 6.8 in, or in specification of an electronic shelf label ranging from 2.9 in to 5.6 in.

In some embodiments, the multifunctional display device 100 of the present invention further includes a transmission port (not shown in the drawings) in signal communication with the display unit 110. The transmission port may be an interface supporting the universal serial bus, such as connectors of USB 2.0, USB 3.0, USB 4.0, USB-C, etc. The transmission port may be an interface supporting the Ethernet connector, such as connectors of CAT5e, CAT6A, CAT7, CAT8, etc. The multifunctional display device 100 of the present invention further includes a wireless transmission unit (not shown in the drawings), which supports Near-field communication (NFC), the Bluetooth communication protocol, the WIFI communication based on IEEE 802.11, or the 2G, 3G, 4G, and 5G mobile communication. Through the abovementioned wired or wireless transmission, the distributor may modify the contents presented by the display unit 110 anytime and monitor the data of the multifunctional display device 100 in real time, whereby the application of the multifunctional display device 100 is expanded.

Refer to FIG. 1. In some embodiments, the display unit 110 includes a press button 150. The user may use the press button 150 to perform fundamental operations of the display unit 110, which may be but are not limited to be switching on/off the power and controlling the displayed contents. The display unit of the present invention has a battery unit (not shown in the drawings) built therein. In some embodiments, the display unit 110 may be powered via a wired charging method or a wireless charging method. For the wired charging method, the display unit 110 has a charging port 116; the user may use the electricity charging port 116 to supply power to the display unit 110 or charge the display unit 110. The charging port 116 may be an interface for at least one of USB A, Micro B, Lighting, and Type-C. In some embodiments, the display unit 110 also includes a cover for the charging port 116 lest ash or humidity enter the charging port 116. For the wireless charging method, the display unit 110 has a receiving coil (not shown in the drawings). The receiving coil reacts to the variation of the magnetic field of the emitting coil and generates induced current for supplying power to the display unit 110 or charging the display unit 110.

It should be pointed out: the embodiments described above are only to exemplify the present invention but not to limit the scope of the present invention. The modifications or variations made by the persons skilled in the art according to the spirit of the present invention would not depart from the present invention and should be included by the scope of the present invention.

What is claimed is:

1. A multifunctional display device, comprising
a display unit, including a display surface, a rear surface opposite to the display surface, a first side, and a second opposite to the first side; and
a support member, disposed on the rear surface and near the first side, and including a first region near the first side, a second region near the second side, and a reverse hanging unit disposed on the second region,
wherein the reverse hanging unit is used to reversely hang the display unit onto a supporter.

2. The multifunctional display device according to claim 1, wherein the display unit has at least one oblique plane on the first side; the at least one oblique plane is inclined by an angle ranging from 145 degrees to 175 degrees.

3. The multifunctional display device according to claim 1, wherein the reverse hanging unit is a groove.

4. The multifunctional display device according to claim 3, wherein the groove includes a stop element, which is used to prevent the reverse hanging unit from departing from the supporter.

5. The multifunctional display device according to claim 3, wherein the groove includes a recess facing the second side.

6. The multifunctional display device according to claim 1, wherein the reverse hanging unit includes at least one hole.

7. The multifunctional display device according to claim 1, further comprising a transmission port, which is in signal communication with the display unit and enables the display unit to exchange packets with external devices.

8. The multifunctional display device according to claim 1, further comprising a wireless transmission unit, which is in signal communication with the display unit and enables the display unit to exchange packets with external devices.

9. The multifunctional display device according to claim 1, further comprising a support base, wherein the support member has a press-fit module disposed on the first region; the support base is used to be press-fitted to the press-fit module, such that the display unit can stand on a plane.

10. The multifunctional display device according to claim 1, wherein the display unit includes a battery unit built therein and a charging interface electrically connected with the battery unit.
